(19) United States
(12) Patent Application Publication
(10) Pub. No.: US 2013/0234138 A1
(43) Pub. Date: Sep. 12, 2013

(54) ELECTRICAL TEST STRUCTURE FOR DETERMINING LOSS OF HIGH-K DIELECTRIC MATERIAL AND/OR METAL GATE MATERIAL

(71) Applicant: Robert C. Lutz, Dresden (DE)

(72) Inventor: Robert C. Lutz, Dresden (DE)

(73) Assignee: GLOBALFOUNDRIES INC., Grand Cayman (KY)

(21) Appl. No.: 13/417,428

(22) Filed: Mar. 12, 2012

(51) Int. Cl. H01L 23/58

(52) U.S. Cl. 257/48; 257/E23.002

(57) ABSTRACT

Disclosed herein are various electrical test structures for evaluating semiconductor devices that employ high-k dielectrics and/or metal gate electrode structures. In one example, the test structure disclosed herein includes a first resistor comprised of at least one of a high-k layer of insulating material or a metal layer and a silicon-containing material layer and first and second spaced-apart metal silicide regions formed on the silicon-containing material layer, wherein the silicon-containing layer further comprises a non-silicided region positioned between the first and second spaced-apart metal silicide regions.

### BACKGROUND OF THE INVENTION

1. Field of the Invention

Generally, the present disclosure relates to the manufacture of sophisticated semiconductor devices, and, more specifically, to various electrical test structures for evaluating semiconductor devices that employ high-k dielectrics and/or metal gate electrode structures.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NFET and PFET transistors) represent one important type of circuit element used in manufacturing such integrated circuit devices. A field effect transistor, irrespective of whether an NFET transistor or a PFET transistor is considered, typically comprises doped source and drain regions that are formed in a semiconducting substrate that are separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

For many early device technology generations, the gate electrode structures of most transistor elements have been made from a plurality of silicon-based materials, such as a silicon dioxide and/or silicon oxynitride gate insulation layer, in combination with a polysilicon gate electrode. However, as the channel length of aggressively scaled transistor elements has become increasingly smaller, many newer generation devices employ gate electrode stacks comprising alternative materials in an effort to avoid the short-channel effects which may be associated with the use of traditional silicon-based materials in reduced channel length transistors. For example, in some aggressively scaled transistor elements, which may have channel lengths on the order of approximately 14-32 nm, gate electrode stacks comprising a so-called high-k dielectric/metal gate (HK/MG) configuration have been shown to provide significantly enhanced operational characteristics over the heretofore more commonly used silicon dioxide/polysilicon (SiO/poly) configurations. These high-k dielectric materials (k value greater than 10) may include, for example, hafnium oxide, zirconium oxide, etc. Illustrative metal gate electrode materials include, for example, one or more layers of titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi) and the like. The HK/MG structures may be formed using so-called “gate-first” or “gate-last” techniques.

To make an integrated circuit on a semiconducting substrate, the various semiconductor devices, e.g., transistors, capacitors, etc., are electrically isolated from one another by so-called isolation structures. Currently, most sophisticated integrated circuit devices employ so-called shallow trench isolation (STI) structures. As the name implies, STI structures are made by forming a relatively shallow trench in the substrate and thereafter filling the trench with an insulating material, such as silicon dioxide. One technique used to form STI structures initially involves growing a pad oxide layer on the substrate and depositing a pad nitride layer on the pad oxide layer. Thereafter, using traditional photolithography and etching processes, the pad oxide layer and the pad nitride layer are patterned. Then, an etching process is performed to form trenches in the substrate for the STI structure using the patterned pad oxide layer and pad nitride layer as an etch mask. Thereafter, a deposition process is performed to overfill the trenches with an insulating material, such as silicon dioxide. A chemical mechanical polishing (CMP) process is then performed using the pad nitride layer as a polish stop layer to remove the excess insulation material. Then, a subsequent deglazing (etching) process may be performed to insure that the insulating material is removed from the surface of the pad nitride layer. This deglaze process removes some of the STI structures.

Numerous processing operations are performed in a very detailed sequence, or process flow, to form integrated circuit devices, e.g., deposition processes, etching processes, heating processes, masking operations, etc. One problem that arises with current processing techniques is that, after the STI regions are formed, at least portions of the STI regions are exposed to many subsequent etching or cleaning processes that tend to consume, at least to some degree, portions of the STI structures subjected to such etching processes. As a result, the STI structures may have an uneven upper surface and may not perform their isolation function as intended, which may result in problems such as increased leakage currents, etc. Furthermore, since the erosion of the STI structures is not uniform across a die or a wafer, such structures may have differing heights, which can lead to problems in subsequent processing operations. For example, such height differences may lead to uneven surfaces on subsequently deposited layers of material, which may require additional polishing time in an attempt to planarize the surface of such layer. Such additional polishing may lead to the formation of additional particle defects, which may reduce device yields.

One particular problem arising in connection with the manufacture of HK/MG gates is that, when the gate structure passes over or near an STI structure, and gate encapsulation is compromised, the high-k insulating material and/or the metal in the gate electrode, e.g., titanium nitride, can also be attacked by many common cleaning chemicals employed in semiconductor manufacturing operations. For example, the high-k insulating materials and/or the metal portions of the gate electrode may be attacked by hydrogen peroxide that is present to at least some degree in cleaning agents such as ammonium hydroxide, sulphuric acid, hydrochloric acid, etc.

FIGS. 1A-1F are schematic drawings that will be referenced to further explain at least one common form of attack of high-k, metal gate structures. FIG. 1A is an illustrative example of a device 10 having an STI structure 14 formed in a semiconducting substrate 12 that has an upper surface 12S. Typically, after the pad oxide layer and pad nitride layer that are used in forming the STI structure 14 are removed, the upper surface 14S of the STI structure 14 (as initially formed) will be above the level of the surface 12S of the substrate 12. FIG. 1B depicts the STI structure 14 at a later point in fabrication wherein the STI structure 14 has been eroded by various cleaning operations which result in the formation of schematically depicted divots or notches 14D in the STI structure 14. The overall height of the STI structure is also typically reduced to some degree due to the consumption of the STI material during the various cleaning operations. FIG. 1C depicts an illustrative high-k, metal gate structure 16 that is formed above the substrate 12 and the STI structure 14. The cross-sectional view depicted in FIG. 1C is a cross-section taken along the gate width 16W of the device 10. The gate structure 16 is comprised of a high-k insulating layer 16A (e.g., hafnium oxide), a metal layer 16B (e.g., titanium nitride) and a layer of polysilicon 16C. FIG. 1D depicts the device 10 after the gate structure 16 has been patterned to define a gate electrode structure of a transistor to be formed to the right of the isolation structure 12. It is typically a requirement that the end of the gate structure 16 be positioned above an isolation region and not above active silicon. Due to a variety of factors, including the topography differences associated with the formation of the divots 14D in the isolation structure 14, and unequal thicknesses of various material layers that traverse such topography differences, the gate structure 16 tends to exhibit some undesirable outward-flaring or “footing” 17 near the bottom of the gate structure 16 when it is patterned. This footing 17 leaves the high-k gate insulation layer 16A and the metal layer 16B exposed. As shown in FIG. 1E, a sidewall spacer 19 comprised of, for example, silicon nitride, is formed in an effort to fully encapsulate the exposed portions of the high-k gate insulation layer 16A and the metal layer 16B. However, due to the undesirable footing 17, and the anisotropic nature of the etching process that is normally performed to form the spacer 19, the spacer 19 does not always cover the exposed portions of the high-k gate insulation layer 16A and the metal layer 16B. As a result, the high-k gate insulation layer 16A and/or the metal layer 16B may be attacked or consumed by chemical agents, such as hydrogen peroxide that is present to at least some degree in cleaning agents such as ammonium hydroxide, sulphuric acid, hydrochloric acid, etc. This results in the formation of schematically depicted voids 20 (FIG. 1F) on the transistor device which may at least degrade the performance of the transistor or, in a worst-case scenario, lead to complete device failure.

FIG. 2 depicts one illustrative example of a prior art test structure 30 for investigating attacks on high-k metal gate structures. The test structure 30 is generally comprised of a serpentine shaped body or line 34 that passes over or near various active regions 32 formed in a semiconducting substrate. The active regions 32 are bounded by STI regions 33. Conductive contacts 35 are formed on opposite ends of the line 34. The line 34 is generally comprised of a high-k gate insulation layer, a metal layer positioned above the gate insulation layer and a layer of non-silicided polysilicon positioned above the metal layer. Using this test structure 30, chemical attack of the high-k material or the metal layer of the line 34 in the region 36 could be determined by measuring the change in resistance level of the test structure, wherein an increase in the resistance level reflected a loss of some of the metal layer.

The present disclosure is directed to various electrical test structures for evaluating semiconductor devices that employ high-k dielectrics and/or metal gate electrode structures that may at least reduce or eliminate one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various electrical test structures for evaluating semiconductor devices that employ high-k dielectrics and/or metal gate electrode structures. In one example, the test structure disclosed herein includes a first resistor comprised of at least one of a high-k layer of insulating material or a metal layer and a silicon-containing material layer and first and second spaced-apart metal silicide regions formed on the silicon-containing material layer, wherein the silicon-containing layer further comprises a non-silicided region positioned between the first and second spaced-apart metal silicide regions.

In another example, the test structure disclosed herein includes a first resistor comprised of a high-k layer of insulating material, a metal layer positioned above the high-k layer of insulating material and a silicon-containing material layer positioned above the metal layer. In this embodiment, the test structure also includes first and second spaced-apart metal silicide regions formed on the silicon-containing material layer, wherein the first and second spaced-apart metal silicide regions are positioned proximate opposite ends of the first resistor and wherein the silicon-containing layer further comprises a non-silicided region positioned between the first and second spaced-apart metal silicide regions.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1F depict one illustrative prior art structure wherein a high-k insulating material and or a metal gate structure have been subjected to chemical attack;

FIG. 2 depicts an illustrative embodiment of a prior art test structure that may be employed in an attempt to investigate the existence of and/or extent of the chemical attack depicted in FIGS. 1A-1F;

FIGS. 3A-3B are various views of one illustrative embodiment of a novel test structure disclosed herein;

FIGS. 4A-4C are various views of one illustrative embodiment of a resistor structure that may be employed on the novel test structures disclosed herein; and

FIGS. 5A-5C are plan views of various alternative arrangements for the various test structures disclosed herein.

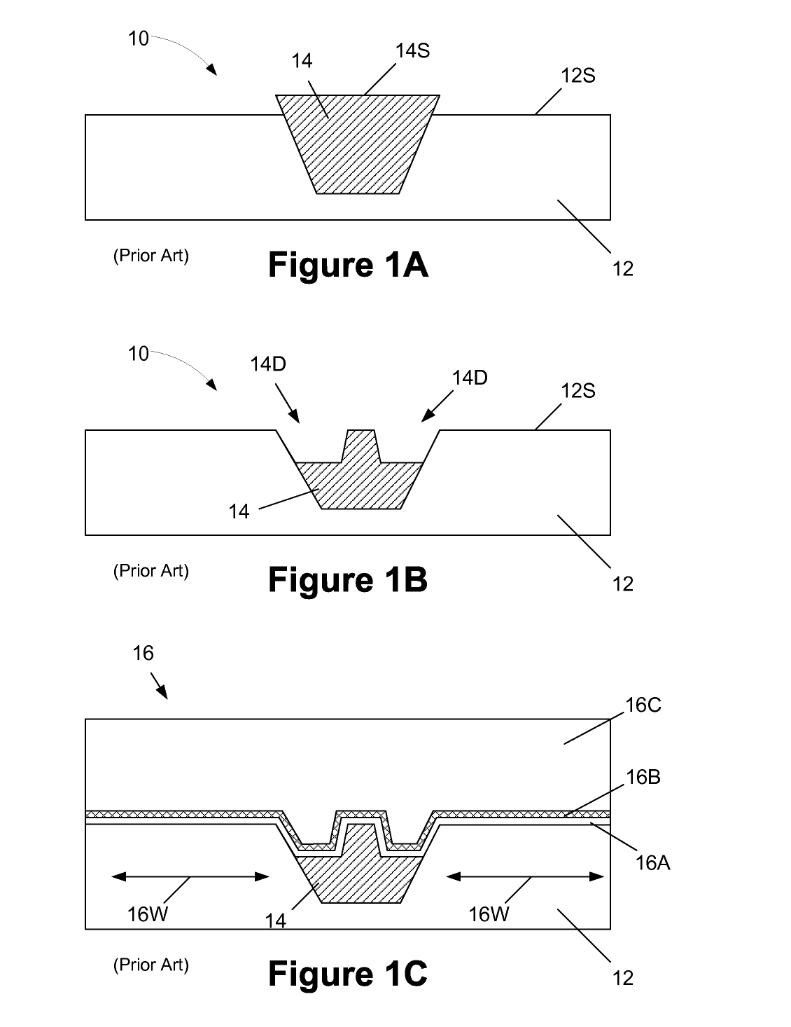

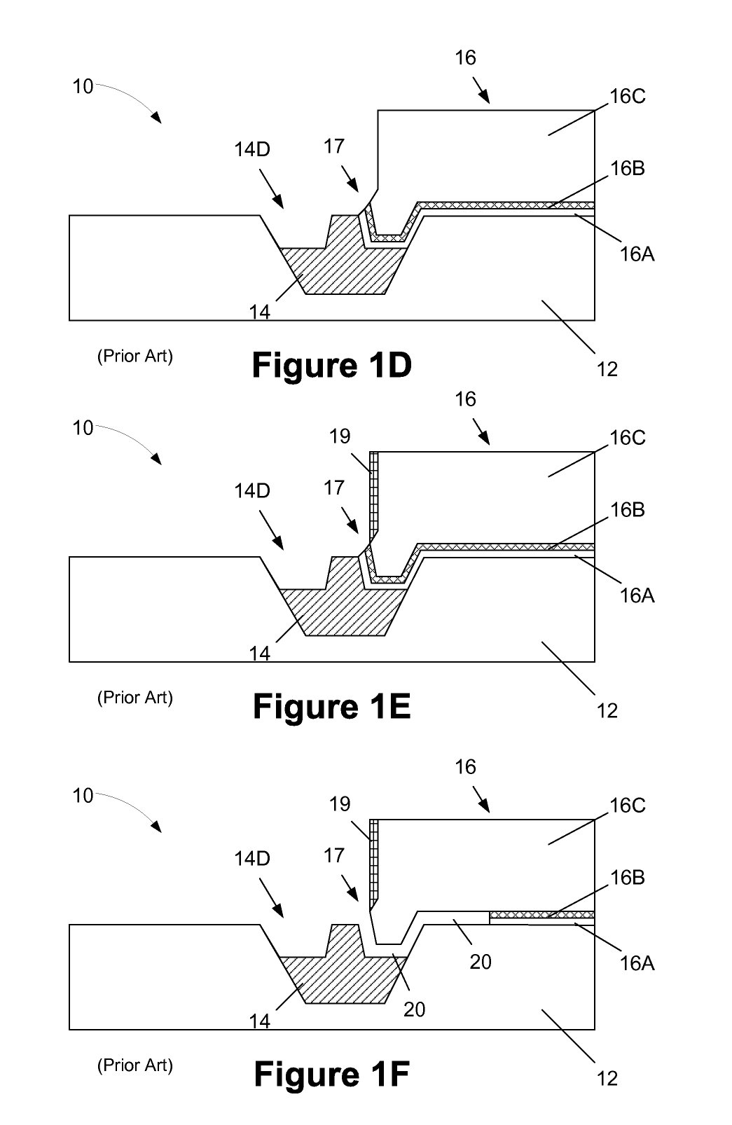

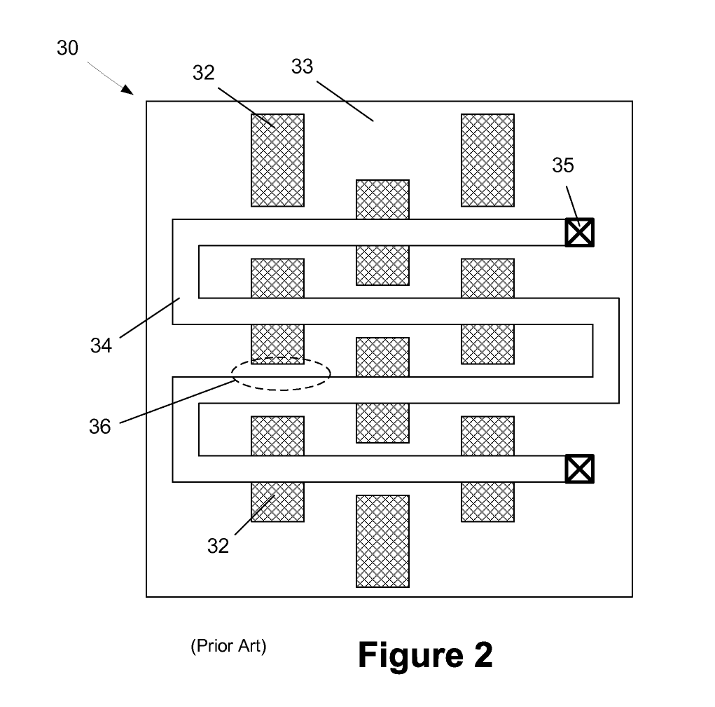

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various electrical test structures for evaluating semiconductor devices that employ high-k dielectrics and/or metal gate electrode structures. As will be readily apparent to those skilled in the art upon a complete reading of the present application, the present method is applicable to a variety of technologies, e.g., NFET, PFET, CMOS, etc., and is readily applicable to a variety of devices, including, but not limited to, ASICs, logic devices, memory devices, etc. With reference to the attached drawings, various illustrative embodiments of the methods and devices disclosed herein will now be described in more detail.

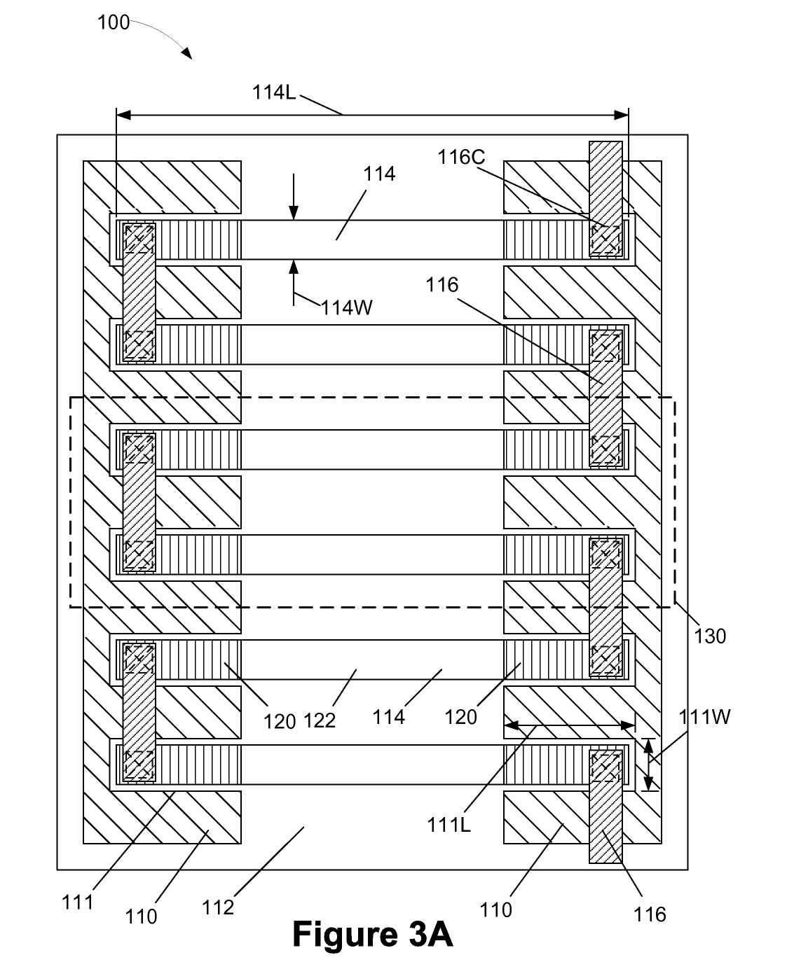

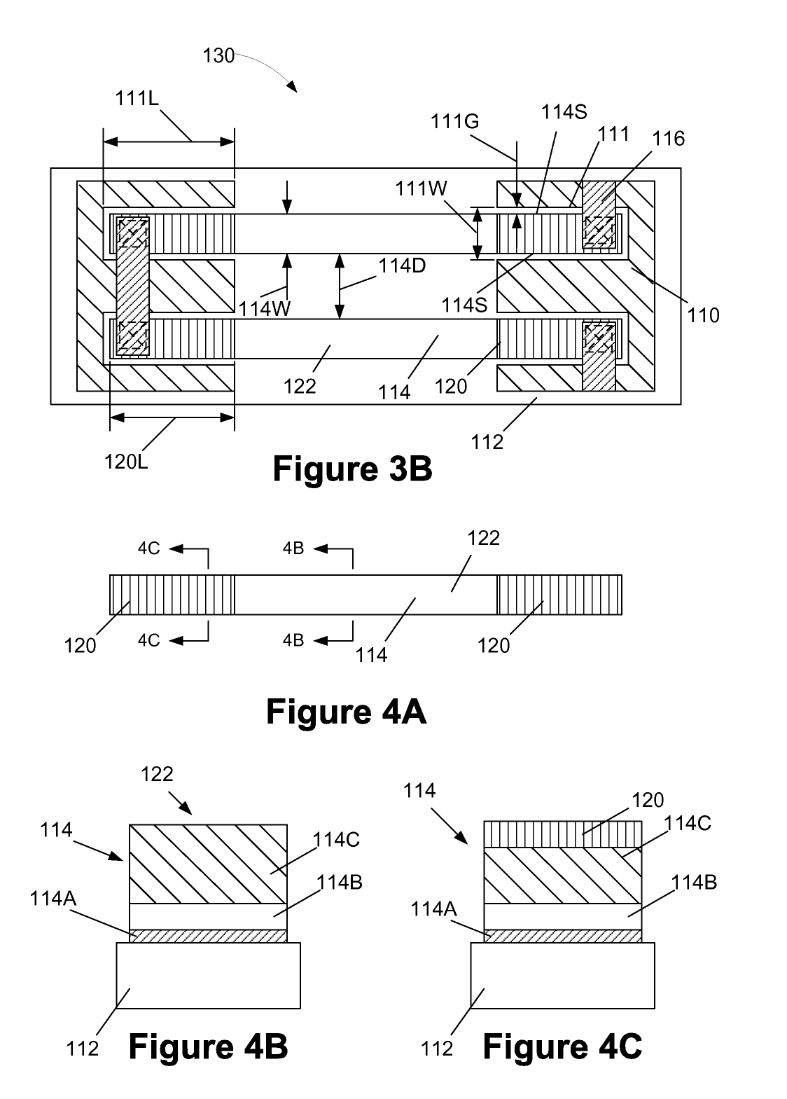

FIG. 3A is a plan view of one illustrative embodiment of a novel test structure 100 disclosed herein. In the illustrative embodiment depicted herein, the test structure 100 is generally comprised of a plurality of line-type resistor structures 114 arranged in a side-by-side pattern. A plurality of active regions 110 are defined in a semiconducting substrate, e.g., silicon, by isolation material 112 formed therein using traditional manufacturing techniques. In this particular embodiment, the active regions 110 have a plurality of recesses 111 defined therein. Opposing ends of the resistor structures 114 are positioned above the isolation material positioned within the recesses 111. The resistor structures 114 have spaced-apart metal silicide regions 120 formed thereon that are separated by a non-silicided portion 122 of the resistor structure 114. A plurality of conductive contacts 116C and interconnect structures 116 conductively couple the resistor structures 114 to one another as depicted. The conductive contacts 116C and the interconnect structures 116 may be made of any conductive material, e.g., titanium, aluminum, copper, etc., and they may be formed using traditional techniques for forming such conductive structures.

The test structure 100 is comprised of a plurality of electrically-connected, repetitive unit cells 130 (depicted by the dashed line). As will be recognized by those skilled in the art after a complete reading of the present application, the size and plot space occupied by the test structure 100 may vary depending upon the particular application and the number of cells 130 in the test structure 100. In one illustrative embodiment, the test structure 100 may have a footprint of about 10,000 μm² (100 μm×100 μm). FIG. 3B is an enlarged view of the illustrative embodiment of the unit cell 130 depicted in FIG. 3A.

The physical dimensions of various portions of the test structure 100 may vary depending upon the particular application. In one illustrative embodiment, the size and spacing of the resistor structures 114, as well as the material of construction used to make the resistor structures 114, may closely mirror gate electrode structures (not shown) for production devices, and the resistor structures 114 may be formed at the same time as such gate electrode structures are formed. In general, in the depicted example, the resistor structures 114 have a length 114L and a width 114W (critical dimension) that may vary depending upon the particular application and the nature of the structures to be tested. In one illustrative embodiment, the length 114L may range up to about 1 μm and the width 114W may be about 14-20 nm based upon current day technology. The recesses 111 in the active regions 110 also have a length 111L and a width 111W that may vary depending upon the particular application. In one illustrative embodiment, the length 111L may be about 50-300 nm and the width 111W may be about 25-100 nm.

Further aspects of the illustrative test structure 100 will now be described with reference to FIG. 3B, which is an enlarged view of the illustrative unit cell 130 shown in FIG. 3A. In the depicted embodiment, the lateral distance 111G between the side 114S of the resistor structure 114 and the active region 110 may be about 10-40 nm. In general, in one embodiment, the test structure 100 should be designed such that the sides 114S of the resistor structures 114 are positioned adjacent the active region 110. The spacing 114D between adjacent resistor structures 114 may be as close as manufacturing capabilities will allow and, in one illustrative embodiment, the spacing 114D may be about 25-100 nm. The axial length 120L of the metal silicide regions 120 may vary depending upon the particular application. In one illustrative embodiment, the axial length 120L for each of the regions 120 maybe about 50-300 nm. In some applications, the axial length of the regions 120 may be different from one another. In one particular example, the combined axial length 120L of both of the illustrative metal silicide regions 120 may be at least about 25-30% of the overall length 114L (FIG. 3A) of the resistor structure 114.

FIG. 4A is a plan view of one illustrative embodiment of the resistor structure 114, while FIGS. 4B and 4C are cross-sectional views of the resistor structure 114 taken as indicated in FIG. 4A. As noted above, the resistor structures 114 have spaced-apart metal silicide regions 120 formed thereon that are separated by a non-silicided portion 122 of the resistor structure 114. As shown in FIG. 4B, the non-silicided portion 122 of the resistor structure 114 is comprised of a high-k gate insulation layer 114A, a metal layer 114B and a silicon-containing layer of material 114C, that are formed above the isolation material 112 (which is not shown in FIG. 4A). The silicon-containing material 114C may be made of any type of material that upon which metal silicide regions may be subsequently formed, for example, a layer of polysilicon, amorphous silicon, silicon germanium or the like. The structure depicted in FIG. 4B may be formed by depositing the corresponding layers of material and thereafter patterning those layers using known photolithography and etching techniques. It should be understood that the present invention is not limited to applications where the resistor structures 114 have the illustrative structure depicted in FIG. 4A. That is, the inventions disclosed herein may also be employed in situations where the resistor structures 114 only employ one of the high-k insulation layer 114A or the metal layer 114B, but not both. As noted previously, the resistor structures 114 may be manufactured at the same time corresponding gate electrode structures are fabricated for production devices. The resistor structures 114 may be formed using so-called “gate-first” or “gate-last” techniques.

The high-k gate insulation layer 114A may be comprised of a high-k material (k value greater than 10) such as, for example, hafnium oxide, zirconium oxide, hafnium silicate, zirconium silicate, titanium oxide, etc., and its thickness may vary depending upon the particular application, e.g., 2-5 nm. The metal layer 114B may be comprised of a variety of metals or metal alloys and its thickness may vary depending upon the particular application. For example, the metal layer 114B may be comprised of titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi) and the like. In one illustrative embodiment, the metal layer 114B may be a layer of titanium nitride having a thickness of about 2-5 nm. Additionally, in some embodiments, the resistor structures 114 may have multiple metal layers. The layer 114C may be comprised of a material that is less electrically conductive than the metal layer 114B. For example, the layer 114C may be a layer of a silicon-containing material, such as polysilicon or amorphous silicon, having a thickness of about 40-80 nm.

FIG. 4C depicts the metal silicide regions 120 that have been formed on portions of the silicon-containing layer 114C. The portion 122 of the resistor feature 114 where it is desired that metal silicide material not be formed may be covered by a masking layer (not shown) during the formation of the metal silicide regions 120. The metal silicide regions 120 depicted herein may be made using a variety of different refractory metals, e.g., nickel, platinum, cobalt, etc., or combinations thereof, and they may be formed using techniques that are well known to those skilled in the art. The typical steps performed to form metal silicide regions are: (1) depositing a layer of refractory metal; (2) performing an initial heating process causing the refractory metal to react with underlying silicon-containing material; (3) performing an etching process to remove unreacted portions of the layer of refractory metal; and (4) performing an additional heating process to form the final phase of the metal silicide. In one illustrative embodiment, the metal silicide regions 120 may have a thickness of about 10-20 nm.

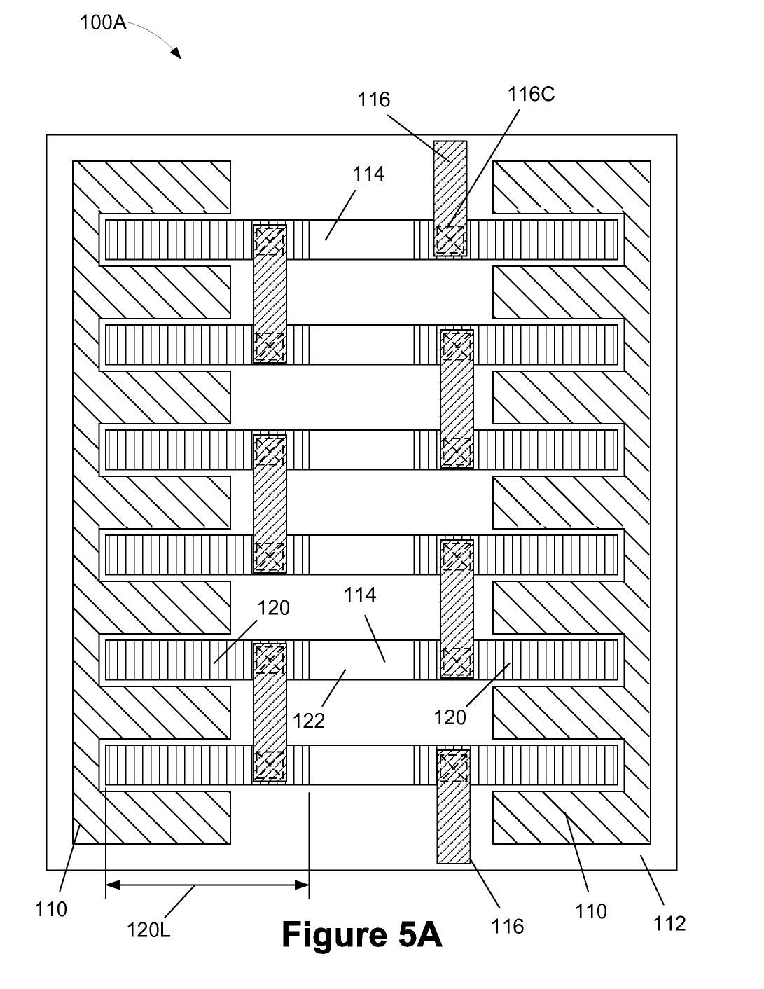

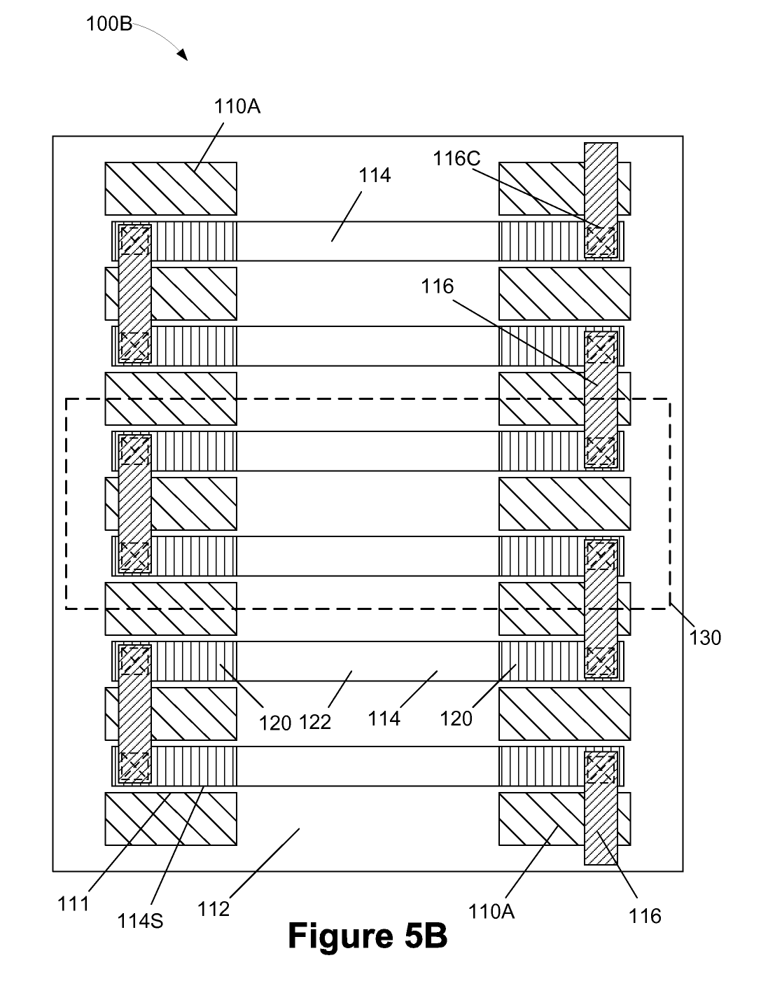

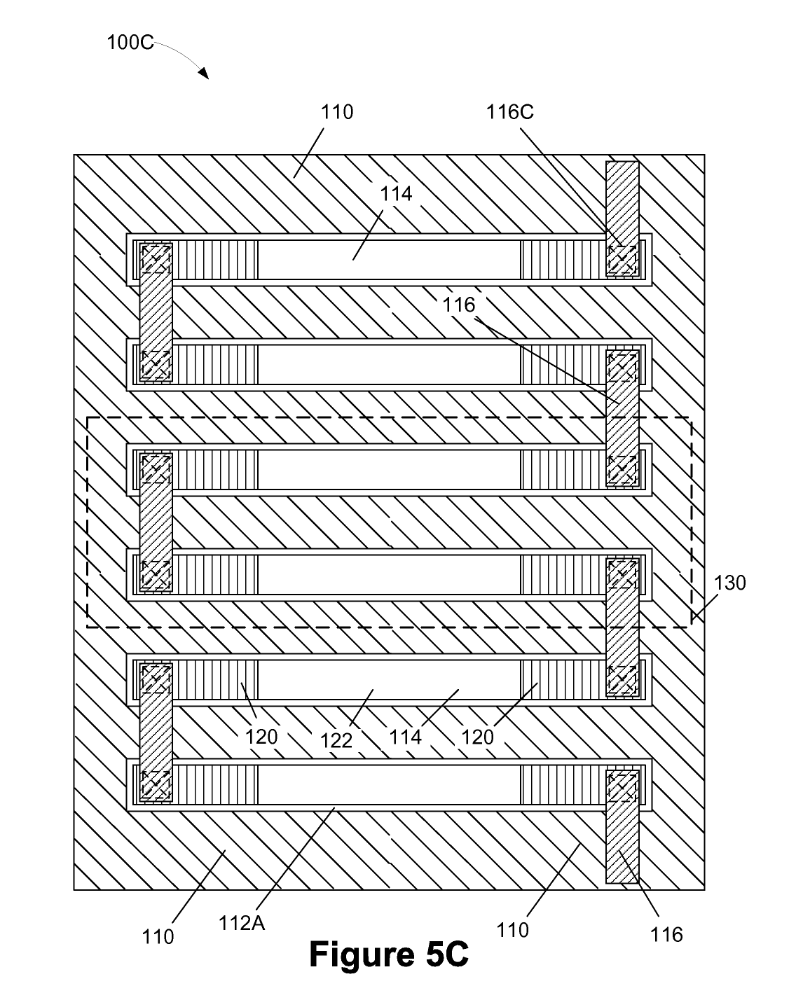

FIGS. 5A-5C depict illustrative alternative configurations of the test structure 100 disclosed herein. Relative to the illustrative test structure 100 depicted in FIG. 3A, in illustrative test structure 100A depicted in FIG. 5A, the axial length 120L of the metal silicide regions 120 is greater and the location of the conductive contacts 116C and the interconnect structure 116 on the resistor structures 114 is more inward on the test structure 100A.

The illustrative test structure 100B depicted in FIG. 5B is comprised of a plurality of isolated active regions 110A that are defined by the isolation material 112. The isolated active regions 110A are positioned adjacent the sides 114S of the resistor structure 114. This configuration is in contrast with the two continuous active regions 110 shown in FIG. 3A for the test structure 100.

The illustrative test structure 100C depicted in FIG. 5C is comprised of a plurality of line-type isolation regions 112A defined in the active area 110, wherein the resistor structures 114 are positioned above the line-type isolation features 112A. The line-type isolation features 112A may be formed by etching a plurality of trenches in the substrate and thereafter filling the trench with an appropriate material, such as silicon dioxide. A chemical mechanical polishing process may then be performed to polarize the surface of the silicon dioxide material with the surface of the substrate.

Of course, the resistor features 114 may also have encapsulation structures, like sidewall spacers (not shown), that reflect the use of such encapsulation structures on production devices. As noted in the background section of the application, the high-k gate insulation layer 114A and/or the metal layer 114B may be attacked or consumed by various chemicals, e.g., hydrogen peroxide, used in various cleaning operations. Over time, the attack on the high-k insulating layer 114A and/or the metal layer 114B will be significant enough that a change in the resistance of the resistor structure 114 can be detected, thereby indicating the presence of a problem that may warrant further attention.

The various embodiments of the presently disclosed test structure 100 may be used to evaluate whether or not such attacks have occurred. More specifically, since the metal silicide regions 120 are spaced apart on the silicon-containing material layer 114C, i.e., the metal silicide regions 120 are non-continuous, the metal layer 114B is the most conductive layer of the resistor structure 114. Accordingly, the metal layer 114B will be the primary carrier of electrical current. The resistance of a control test structure 100 that is unaffected by the aforementioned chemical attacks, or the test structure under observation immediately after it is patterned, may be determined by appropriate testing, i.e., by applying a voltage to the test structure 100 via the contacts 116C and interconnect structure 116, measuring the current flowing as a result of the applied voltage and calculating the resistance of the control test structure 100 from those two values. To determine if any chemical attack has occurred on the high-k insulating layer 114A and/or the metal layer 114B, the resistance of the subject test structure 100 may be determined after it is has been subjected to any number of processing operations, e.g., cleaning operations. If the metal layer 114B has been attacked and consumed to any appreciable degree, the resistance of the subject test structure 100 should increase relative to the resistance of the control test structure or the test structure as originally patterned. The resistance of the subject test structure 100 may be determined as described previously for the control test structure 100. Thus, an increase in the resistance of the subject test structure 100 is indicative that encapsulation (if present) has failed at some location on the subject test structure 100. The magnitude of the change in resistance, coupled with knowledge of the processing operations performed on the subject test structure 100, may give some indication as to the scope or extent of the chemical attack. If desired, this change in the electrical characteristics may also be correlated with other processing parameters, such as yield loss. Of course, variations of other electrical properties of the subject test structure may also be indicative of the loss of encapsulation and the chemical attack of the high-k insulating layer 114A and/or the metal layer 114B. For example, if the same voltage is applied to the subject test structure immediately after it is patterned and after it has been subjected to one or more cleaning operations, then a relatively low current that passes through the subject test structure 100 is also indicative that the high-k insulating layer 114A and/or the metal layer 114B has been attacked. That is, for the same applied voltage, a reduced current readout is an indication that there has been a loss of some of the metal layer 114B due to chemical attack. However, since the materials of most metal layers 114B used in device fabrication have a similar etch rate to most high-k insulating materials used in device fabrication (typically within a factor of 2 of each other), the detected loss of metal using the test structure 100 serves as a relatively good proxy for the loss of high-k material as well. The loss of either the high-k material or metal gate materials from an active transistor is sufficient to degrade the performances of the transistor and, in some cases, may cause the transistor to cease functioning.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A test structure, comprising:
a first resistor comprised of at least one of a high-k layer of insulating material or a metal layer and a silicon-containing material layer; and
first and second spaced-apart metal silicide regions formed on said silicon-containing material layer, wherein said silicon-containing layer further comprises a non-silicided region positioned between said first and second spaced-apart metal silicide regions.

2. The test structure of claim 1, wherein said first resistor is a line-type feature and wherein at least a portion of said first resistor is formed above an isolation material.

3. The test structure of claim 1, wherein said first resistor is a line-type feature and wherein an entirety of said first resistor is formed above an isolation material.

4. The test structure of claim 1, wherein said first and second spaced-apart metal silicide regions are positioned proximate opposite ends of said first resistor.

5. The test structure of claim 1, wherein said first resistor is a line-type feature with sides and wherein at least a portion of said sides of said resistor are positioned adjacent an active region of a semiconducting substrate.

6. The test structure of claim 1, wherein said first resistor has a total axial length and said first and second spaced-apart metal silicide regions have a combined axial length that is at least about 25-30 percent of said total axial length of said first resistor.

7. The test structure of claim 1, further comprising first and second spaced-apart active regions, each of which have a three-sided recess defined therein, wherein a first end of said first resistor is positioned above the area defined by the recess defined in said first active region and wherein a second end of said first resistor is positioned above the area defined by the recess defined in said second active region.

8. The test structure of claim 1, further comprising first and second spaced-apart isolated active regions, wherein said first plurality of spaced-apart isolated active regions are placed on opposite sides of a first end of said first resistor and wherein said second plurality of spaced-apart isolated active regions are placed on opposite sides of a second end of said first resistor.

9. The test structure of claim 1, wherein said silicon-containing material is one of polysilicon or amorphous silicon.

10. A test structure, comprising:
a first resistor comprised of a high-k layer of insulating material, a metal layer positioned above said high-k layer of insulating material and a silicon-containing material layer positioned above said metal layer; and
first and second spaced-apart metal silicide regions formed on said silicon-containing material layer, wherein said first and second spaced-apart metal silicide regions are positioned proximate opposite ends of said first resistor, and wherein said silicon-containing layer further comprises a non-silicided region positioned between said first and second spaced-apart metal silicide regions.

11. The test structure of claim 10, wherein said first resistor is a line-type feature and wherein at least a portion of said first resistor is formed above an isolation material.

12. The test structure of claim 10, wherein said first resistor is a line-type feature and wherein an entirety of said first resistor is formed above an isolation material.

13. The test structure of claim 10, wherein said first resistor is a line-type feature with sides and wherein at least a portion of said sides of said resistor are positioned adjacent an active region of a semiconducting substrate.

14. The test structure of claim 10, wherein said first resistor has a total axial length and said first and second spaced-apart metal silicide regions have a combined axial length that is at least about 25-30 percent of said total axial length of said first resistor.

15. The test structure of claim 10, further comprising first and second spaced-apart active regions, each of which have a three-sided recess defined therein, wherein a first end of said first resistor is positioned above the area defined by the recess defined in said first active region and wherein a second end of said first resistor is positioned above the area defined by the recess defined in said second active region.

16. The test structure of claim 10, further comprising first and second spaced-apart isolated active regions, wherein said first plurality of spaced-apart isolated active regions are placed on opposite sides of a first end of said first resistor and wherein said second plurality of spaced-apart isolated active regions are placed on opposite sides of a second end of said first resistor.

17. A test structure, comprising:
a first resistor comprised of a high-k layer of insulating material, a metal layer positioned above said high-k layer of insulating material and a silicon-containing material layer positioned above said metal layer, wherein said first resistor has a total axial length; and
first and second spaced-apart metal silicide regions formed on said silicon-containing material layer, wherein said first and second spaced-apart metal silicide regions are positioned proximate opposite ends of said first resistor, said first and second spaced-apart metal silicide regions having a combined axial length that is at least about 25-30 percent of said total axial length of said first resistor, and wherein said silicon-containing layer further comprises a non-silicided region positioned between said first and second spaced-apart metal silicide regions.

18. The test structure of claim 17, wherein said first resistor is a line-type feature and wherein at least a portion of said first resistor is formed above an isolation material.

19. The test structure of claim 17, wherein said first resistor is a line-type feature and wherein an entirety of said first resistor is formed above an isolation material.

20. The test structure of claim 17, wherein said first resistor is a line-type feature with sides and wherein at least a portion of said sides of said resistor are positioned adjacent an active region of a semiconducting substrate.

21. The test structure of claim 17, further comprising first and second spaced-apart active regions, each of which have a three-sided recess defined therein, wherein a first end of said first resistor is positioned above the area defined by the recess defined in said first active region and wherein a second end of said first resistor is positioned above the area defined by the recess defined in said second active region.

22. The test structure of claim 17, further comprising first and second spaced-apart isolated active regions, wherein said first plurality of spaced-apart isolated active regions are placed on opposite sides of a first end of said first resistor and wherein said second plurality of spaced-apart isolated active regions are placed on opposite sides of a second end of said first resistor.
